(19) United States
(12) Patent Application Publication
(10) Pub. No.: US 2005/0048742 A1
(43) Pub. Date: Mar. 3, 2005

(54) Multiple grow-etch cyclic surface treatment for substrate preparation

(75) Inventors: Anthony Dip, Cedar Creek, TX (US); Pradip K. Roy, Orlando, FL (US); Raymond Joe, Austin, TX (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/647,534

(22) Filed: Aug. 26, 2003

(51) Int. Cl. H01L 21/302; H01L 21/322; H01L 21/461

(52) U.S. Cl. 438/476

(57) ABSTRACT

This invention provides a method for modifying the surface properties of a Si or Si alloy substrate by performing repeated etch-grow cycles of thermal oxide to yield a more defect free substrate with a more uniform nucleating surface which provides an improved interface for dielectric formation. Additionally, this method of processing does not expose the substrate to ambient atmosphere and preserves the improved surface until subsequent processing steps are performed.

### FIELD OF THE INVENTION

The present invention is generally related to semiconductor processing systems and methods, and more particularly related to semiconductor processing systems and methods used to provide improved surfaces regions on substrates.

### BACKGROUND OF THE INVENTION

Silicon substrate damage and surface contamination exists on the surface or in the region just below the surface of a semiconductor substrate. These defects occur as a natural side effect of the manufacturing process for making devices and integrated circuits, and generally cause reduced performance and/or reliability of the semiconductor device or integrated circuit. To address this problem, current substrate preparation processes use a sacrificial oxide method to remove the upper surface layers of the substrate containing damage. In this method, a silicon dioxide film is grown typically greater than 50 Å in thickness for the express purpose of removal before processing is completed. This sacrificial oxide film protects the substrate from contamination exposed to it, or is employed to remove a surface layer that may contain structural defects or other imperfections or contamination.

The present inventors have recognized, however, that use of a sacrificial oxide layer greater than 50 Å in thickness may create defects in the substrate that did not exist prior to creating the sacrificial oxide layer. These newly created defects impair the performance and/or reliability of devices and ICs using the substrate.

### SUMMARY OF THE INVENTION

Accordingly, one object of the present invention is to solve and/or reduce the above-described problems.

Another object of the present invention is to improve the surface properties of a Si or Si alloy, such as Si(x)Ge(y).

Yet another object of the present invention is to yield a more defect free substrate with a more uniform nucleating surface, which provides an improved interface for dielectric formation.

These and other objectives are performed by a method, apparatus, and computer readable medium for processing a substrate in accordance with the present invention. The method upon which the apparatus and computer readable medium is based includes growing a first ultra-thin oxide layer on a surface of the substrate to consume defects in a surface region of the substrate and etching away at least a portion of the first ultra-thin oxide layer to remove at least some of the consumed defects from the substrate and reveal a subsurface of the substrate. A second ultra-thin oxide layer is then grown on the subsurface of the substrate to consume more defects in the surface region of the substrate, and etching away at least a portion of the second ultra-thin oxide layer to remove at least some of the consumed more defects from the substrate.

The first and second ultra-thin oxide layers each may be grown as an oxide layer having a thickness of between approximately 5 Å and approximately 15Å. The method may also include monitoring the surface region of the substrate, and repeatedly growing an additional ultra-tin oxide layer to consume additional defects and etching the additional oxide layer to remove the consumed additional defects based on the monitoring of the surface region. Monitoring includes using high-resolution transmission electron microscopy (HRTEM) data.

The method may be performed on a substrate including at least one of silicon and a silicon alloy. The etching steps may include at least one of a wet etching process and a dry vapor etching process. At least one of the etching steps may include using a gas including at least one of a hydrogen containing gas, a fluorine containing gas, and a chlorine containing gas. The gas may include using a gas having at least one of HF, H2, F2, and ClF3.

The method may include forming an additional layer on one of the first and second oxide layer, or processing a plurality of substrates including the substrate, wherein each of the growing steps and each of the etching steps is performed on each of the plurality of substrates.

### BRIEF DESCRIPTION OF THE DRAWINGS

A more complete appreciation of the invention and many of the attendant advantages thereof will become readily apparent with reference to the following detailed description, particularly when considered in conjunction with the accompanying drawings, in which:

FIG. 1 shows an exemplary block diagram of a processing system in accordance with one embodiment of the present invention;

FIG. 2 shows an exemplary block diagram of another processing system in accordance with one embodiment of the present invention;

FIG. 3 shows an exemplary block diagram of another processing system in accordance with an embodiment of the present invention;

FIGS. 4A-4C show simplified views of processing steps in an exemplary sacrificial oxide layer process;

FIGS. 5A-5G show simplified views of processing steps in accordance with an embodiment of the present invention;

FIG. 6 shows a flow diagram for a method of processing a substrate in accordance with an embodiment of the present invention;

FIG. 7 shows a block diagram of a computer system that may be implemented in accordance with the present invention.

### DETAILED DESCRIPTION OF AN EMBODIMENT

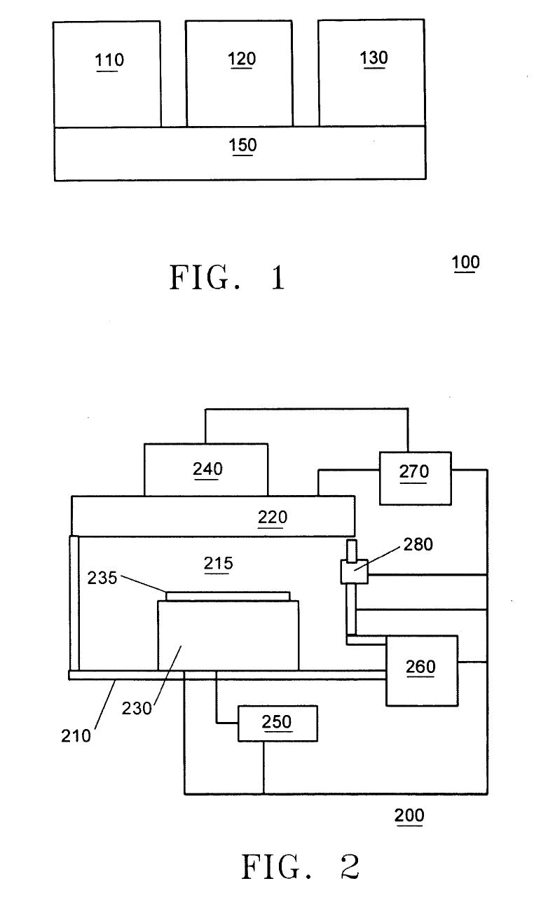

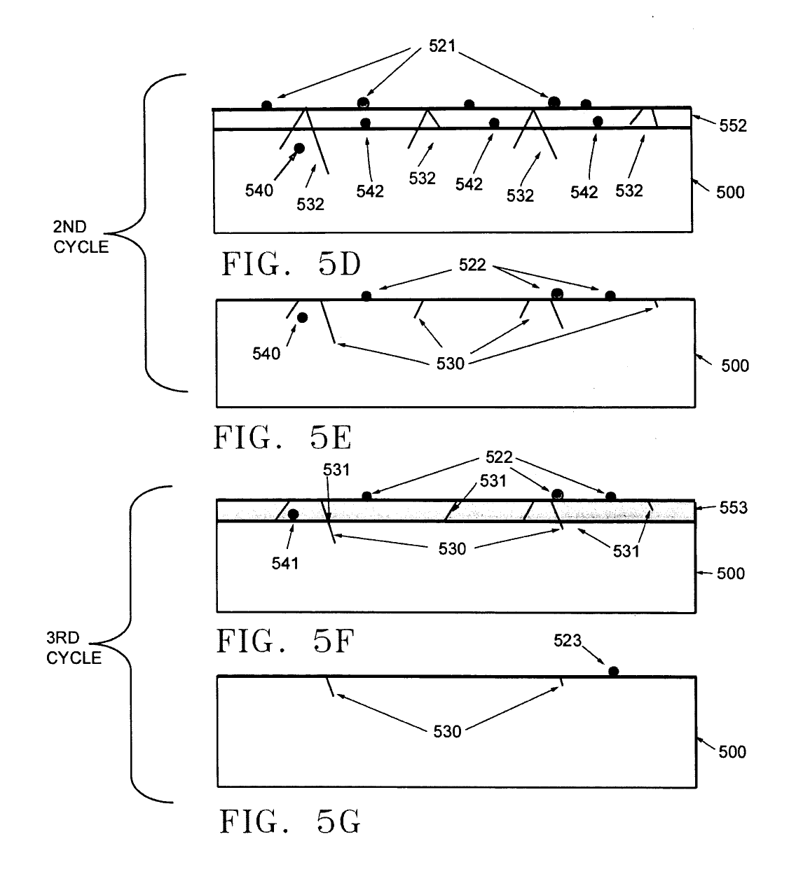

Referring now to the drawings, FIG. 1 shows an exemplary block diagram of a processing system in accordance with one embodiment of the present invention. Processing system 100 includes a number of processing modules 110-130 coupled to a transfer system 150 and may be used to perform the processing steps of the present invention, including those described with respect to FIGS. 5A-5G below, for example. Although three processing modules are shown in FIG. 1, any number of processing modules can be used. For example, process modules can include a dry etching process module, a wet etching process module, a thermal oxidation process module, a spin-on-glass (SOG) process module, a spin-on-dielectric (SOD) process module for measuring substrate parameters including internal and external properties, a chemical vapor deposition (CVD) process module, a physical vapor deposition (PVD) process module, an ionized physical vapor deposition (iPVD) process module, an atomic layer deposition (ALD) process module, a rapid thermal processing (RTP) module, a batch diffusion furnace, and/or combinations thereof.

A processing system as shown in FIG. 1 can be use to perform various surface treatments, and these can include chemistries to remove organic or inorganic contamination on substrates (Si or others) before processing occurs. In addition, processing system 100 can be used to perform surface treatments for the removal of native oxide films before film deposition (as in the case of epitaxial silicon) or before thermal diffusion (as in the case of silicon dioxide). In general, processing system 100 can be used for the removal of a defective film (native oxide) that would otherwise compromise the final film product if left intact. For example, processing system 100 can employ reducing environments and chemistries such as HF, H2, F2, and other compounds containing active species of H, F, Cl, or mixtures of such compounds.

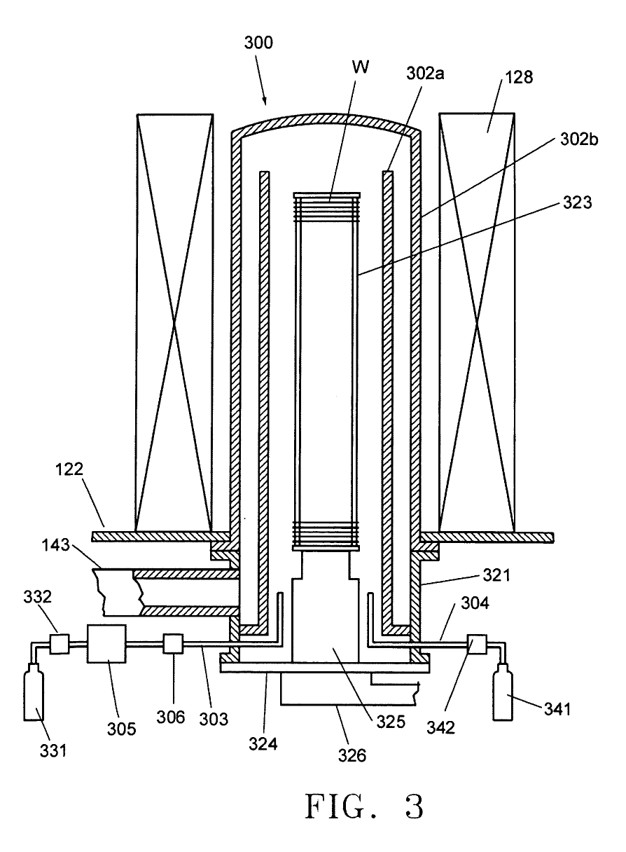

FIG. 2 shows an exemplary block diagram of another processing system in accordance with an embodiment of the present invention. The processing system of FIG. 2 can be used to perform the processing steps of the present invention, including those described with respect to FIGS. 5A-5G for example. In the illustrated embodiment, a single process module 210 is shown, but a single module is not required for the invention. For example, process module 210 can include an etching chamber, such as a plasma etcher or a thermal processing chamber, such as a thermal oxidation chamber.

In the illustrated embodiment, processing system 200 includes processing chamber 210, upper assembly 220, substrate holder 230 for supporting substrate 235, gas supply system 240, pumping system 260, and controller 270. Pumping system 260 can provide a controlled pressure in processing chamber 210, for example, while processing chamber 210 may facilitate the formation of a processing gas in a process space 215, which is adjacent substrate 235. The processing system 200 can be configured to process 200 mm substrates, 300 mm substrates, or larger substrates. Alternately, the processing system can operate by generating plasma in one or more processing chambers.

Substrate 235 can be, for example, transferred into and out of processing chamber 210 through a slot valve (not shown) and chamber feed-through (not shown) via robotic substrate transfer system where it can be received by substrate lift pins (not shown) housed within substrate holder 230 and mechanically translated by devices housed therein. Once substrate 235 is received from substrate transfer system, it can be lowered to an upper surface of substrate holder 230.

Substrate 235 can be, for example, affixed to the substrate holder 230 via an electrostatic clamping system. Furthermore, substrate holder 230 can further include a cooling system including a re-circulating coolant flow that receives heat from substrate holder 230 and transfers heat to a heat exchanger system (not shown), or when heating, transfers heat from the heat exchanger system. Moreover, gas can, for example, be delivered to the backside of substrate 235 via a backside gas system to improve the gas-gap thermal conductance between substrate 235 and substrate holder 230. Such a system can be utilized when temperature control of the substrate is required at elevated or reduced temperatures. In other embodiments, heating elements, such as resistive heating elements, or thermoelectric heaters/coolers can be included.

In alternate embodiments, substrate holder 230 can, for example, further include a vertical translation device (not shown) that can be surrounded by a bellows (not shown) coupled to the substrate holder 230 and the processing chamber 210, and configured to seal the vertical translation device from the reduced pressure atmosphere in processing chamber 210. Additionally, a bellows shield (not shown) can, for example, be coupled to the substrate holder 230 and configured to protect the bellows. Substrate holder 230 can, for example, further provide a focus ring (not shown), a shield ring (not shown), and a baffle plate (not shown).

In the illustrated embodiment, shown in FIG. 2, substrate holder 230 can include an electrode (not shown) through which RF power can be coupled to the processing plasma in process space 215. For example, substrate holder 230 can be electrically biased at a RF voltage via the transmission of RF power from RF system 250. The RF bias can serve to heat electrons to form and maintain plasma. In this configuration, the material system can operate as a reactive ion etch (RIE) reactor, wherein the chamber and upper gas injection electrode serve as ground surfaces. A typical frequency for the RF bias can range from 1 MHz to 100 MHz. For example, semiconductor processing systems that use 13.56 MHz for plasma processing are well known to those skilled in the art.

As shown in FIG. 2, upper assembly 220 can be coupled to the processing chamber 210 and configured to perform at least one of the following functions: provide a gas injection system, provide a capacitively coupled plasma (CCP) source, provide an inductively coupled plasma (ICP) source, provide a transformer-coupled plasma (TCP) source, provide a microwave powered plasma source, provide an electron cyclotron resonance (ECR) plasma source, provide a Helicon wave plasma source, and provide a surface wave plasma source.

For example, upper assembly 220 can include an electrode, an insulator ring, an antenna, a transmission line, and/or other RF components (not shown). In addition, upper assembly 220 can include permanent magnets, electromagnets, and/or other magnet system components (not shown). Also, upper assembly 220 can include supply lines, injection devices, mass flow controllers, and/or other gas supply system components (not shown). Furthermore, upper assembly 220 can include a housing, a cover, sealing devices, and/or other mechanical components (not shown).

In an alternate embodiment, processing chamber 210 can, for example, further include a chamber liner (not shown) or process tube (not shown) for protecting the processing chamber 210 from a processing plasma in the process space 215.

In addition, processing system 200 can include a monitoring system 280 coupled to the processing chamber 210. The monitoring system 280 can, for example, include a mass spectrometer system to measure gaseous species in the process gas and other gases in the processing environment. In other embodiments, the monitoring system 280 can be a diagnostic tool capable of performing multiple tasks such as process analysis and process compliance. The monitoring system 280 can be used with controller 270 to determine the status of the process and provide feedback to ensure process compliance. For example, monitoring device 280 can provide for the optical monitoring of process space 215 and/or substrate 235 in order to determine whether an additional oxide growth and etch cycle should be performed.

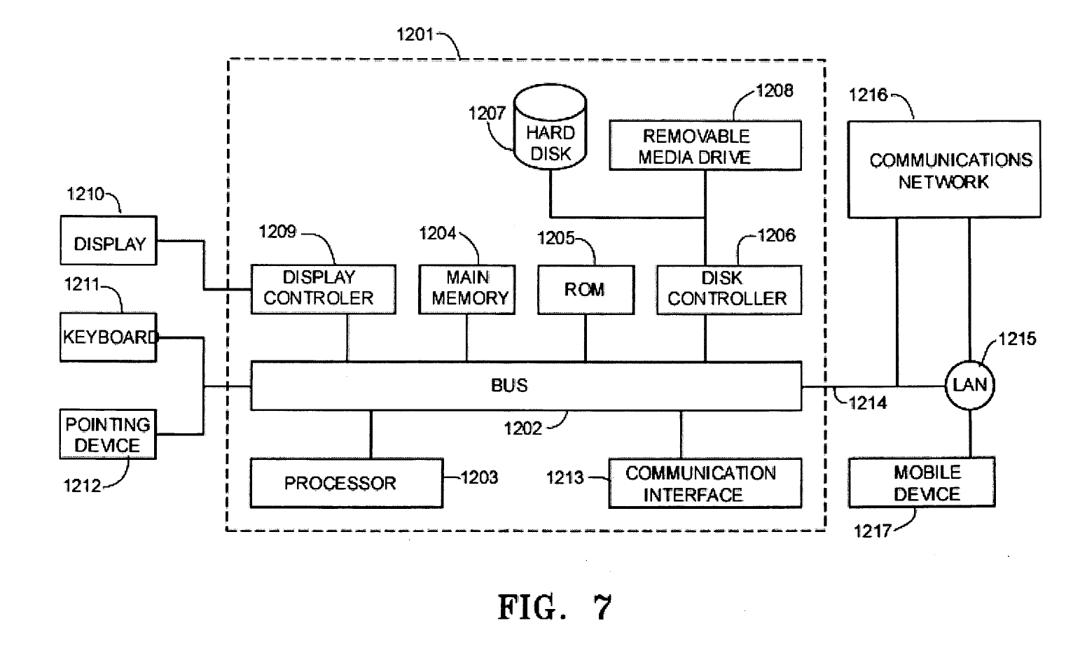

Processing system 200 also includes a controller 270. Controller 270 can be coupled to chamber 210, upper assembly 220, substrate holder 230, gas system 240, RF system 250, pumping system 260, and monitoring device 280. The controller can be configured to provide control data to the monitoring device 280 and receive data such as process data from the monitoring device 280. For example, controller 270 can include a microprocessor, a memory (e.g., volatile and/or non-volatile memory), and a digital I/O port capable of generating control voltages sufficient to communicate and activate inputs to the processing system 200 as well as monitor outputs from the processing system 200. Moreover, the controller 270 can exchange information with chamber 210, upper assembly 220, substrate holder 230, gas system 240, RF system 250, pumping system 260, and monitoring device 280. Also, a program stored in the memory can be utilized to control the aforementioned components of a material processing system 200 according to a process recipe. In addition, controller 270 can be configured to analyze the process data, to compare the process data with target process data, and to use the comparison to change a process and/or control the processing system components. Also, the controller can be configured to analyze the process data, to compare the process data with historical process data, and to use the comparison to predict, and/or declare an endpoint. The controller 270 may be implemented as a general purpose computer such as that described with respect to FIG. 7.

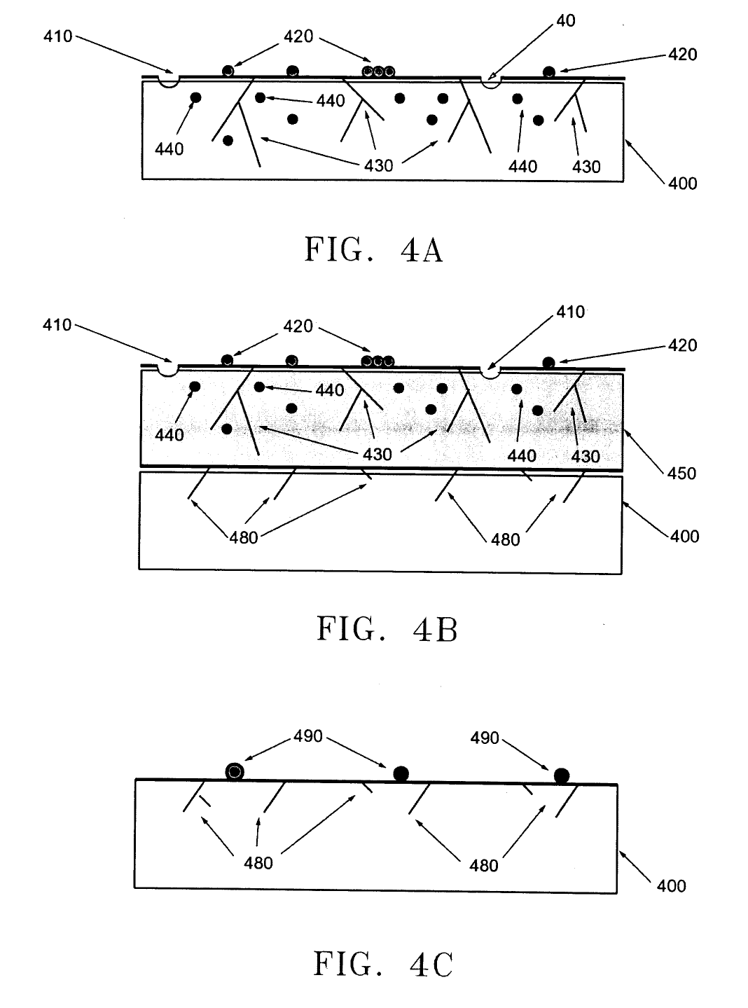

FIG. 3 shows an exemplary block diagram of another processing system in accordance with an embodiment of the present invention. The processing system of FIG. 3 can be used to perform the processing steps of the present invention, including those steps described in FIGS. 5A-5G, for example. In the illustrated embodiment, a batch process module 300 is shown, but this is not required for the invention. For example, process module 300 can be used for an etching process, a deposition process, a cleaning process, and a thermal process.

In the illustrated embodiment, a process module 300 having a double tube structure including an inner tube 302a and outer tube 302b of, e.g., quartz is shown. The process module 300 can include a cylindrical metallic manifold on the bottom side. For example, the top end of the inner tube 302a can be open, and the inner tube 302a can be supported inside of the manifold 321. The top end of the outer tube 302b can be closed, and the bottom end can be connected to the top end of the manifold 321. Base plate 122 can be coupled to outer tube 302b.

As shown in FIG. 3, process module 300 can be used to process a number of wafers W that can be horizontally mounted on the shelves of a wafer boat 323, which serves to hold the wafers at regular intervals in the vertical direction. The wafer boat 323 can be held on a lid 324 via an insulating member 325. The lid 324 can be mounted on a boat elevator 326, which is provided for carrying the wafer boat 323 in and out of the process module 300. When the lid 324 is positioned at the upper limit position, the lid 324 serves to close a bottom end opening of the manifold 321, i.e., a bottom end opening of the reaction vessel constituted by the process module 300 and the manifold 321. In addition, a transfer system (not shown) can be used for transferring the wafers W to and from the wafer boat 323.

Process module 300 further includes a heater 328 that can be positioned around the outer tube 302b. For example, the heater 328 can include a heating resistance member, and the temperature of the heater 328 can be controlled by a controller (not shown).

The manifold 321 can be provided with a plurality of first gas feed pipes 303 serving as gas feed passages for supplying a first process gas into the process module 300, and a second gas feed pipe 304 for supplying a second process gas into the process module 300, and respective process gases are fed from first and second gas supply sources 331 and 341 via the gas supply pipes 303 and 304.

In the first and second gas feed pipes 303 and 341, gas flow control devices 332 and 342 for controlling the flow rates of the gases are provided, respectively. In addition, an exhaust regulator 343 is shown coupled to the manifold 321. In response to a control signal, the opening and closing timing of the devices can be controlled on the basis of a previously inputted process gas feed program during a process, so that the process gas feed timing and the chamber pressure can be controlled.

The first process gas feed can include a heater 305 for preheating the first process gas to a predetermined temperature, and a flow control device 306, which can be an orifice.

A batch process module can be used to carry out the methods of the present invention. For example, a batch process module can be used to form an ultra-thin layer on a number of substrates and/or to remove an ultra-thin layer from a number of substrates.

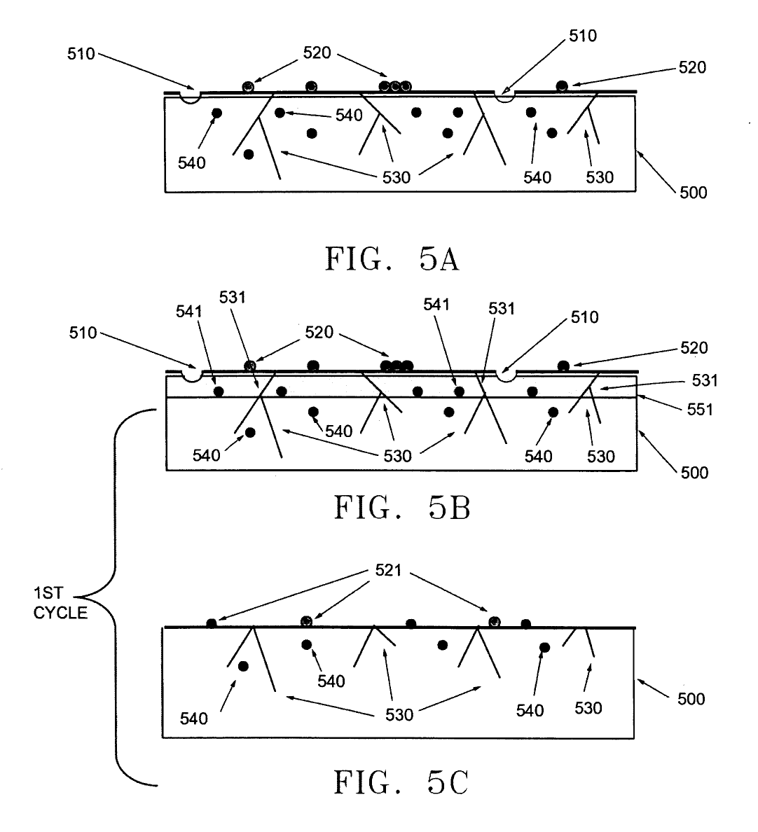

FIGS. 4A-4C show simplified views of processing steps in an exemplary sacrificial oxide layer process that uses a relatively thick oxide layer. As shown in FIG. 4A, a processed Si substrate 400 can have various defects such as surface defects 410, surface contamination 420, structural defects 430, and diffused impurities 440. A sacrificial oxide layer 450 is then formed on the substrate 400 to consume impurities 440 and structural defects 430, as shown in FIG. 4B. The sacrificial oxide layer 450 is typically 40-80 Å thick, which, as recognized by the present inventors, causes the formation of additional interfacial defects 480, due to mechanical stresses caused by the lattice mismatch between the oxide layer 450 and the Si substrate 400. As seen in FIG. 4C, the oxide layer 450 is then removed by wet chemistry processing (usually a dilute HF-water solution), taking with it the original substrate defects 430 and 440 and leaving only some impurities 490 remaining on the surface of the substrate 420.

The present inventors have further recognized, however, that removal of the sacrificial oxide layer 450 leaves the additional interfacial defects 480 remaining in the substrate 400 as shown in FIG. 4C. These defects have the effect of reducing the performance and/or reliability of a device or integrated circuit using the substrate 400. Moreover, the process of removing the thick oxide layer 450 may deteriorate gate-to-gate isolation due to over etching of the field oxidation and can sometimes roughen the surface of the substrate 400. Therefore, while existing sacrificial oxide methods remove some original defects from the substrate, these methods introduce new defects and other problems that impair the performance and/or reliability of devices and ICs using the substrate.

FIGS. 5A-5E show simplified views of processing steps in accordance with an embodiment of the present invention. As shown in FIG. 5A, a processed Si substrate 500 can have defects such as surface defects 510, surface contamination 520, structural defects 530, and diffused impurities 540. As used herein, the term defect is used generally to include any anomaly or undesirable feature in a surface region of a substrate, which can be removed by a sacrificial oxide process. The surface region of the substrate is that region where defects are generally found. The surface region is generally less than about 40 Å thick but varies widely based on the substrate material, and the substrate forming process.

In FIGS. 5B and 5C, a first cycle of the present invention is illustrated. As shown in FIG. 5B, an ultra-thin oxide layer 551 is formed on the substrate 500 to consume some of the defects 510 (surface defects), 531 (structural defects) and 541 (diffused impurities). The ultra-thin oxide layer 551 is preferably from about 5 Å to about 15 Å thick and is more preferably about 10 Å thick. The present inventors have recognized that by creating an ultra-thin oxide layer, the effects of lattice mismatch between the oxide layer and the substrate do not contribute to new defect formation, or the effects are minimized. Thus, as seen in FIG. 5B, new defects are not formed by the ultra-thin oxide growth process. While the above thickness ranges are preferred, it is to be understood that the ultra-thin layer may be any thickness less than 40 Å which is the lower limit of conventional sacrificial oxide processes.

As shown in FIG. 5C, the ultra-thin oxide layer 551 can be etched away thereby removing one or more surface defects 510 and one or more surface contaminants 520. In addition, the etching process can be used to at least partially remove one or more structural defects 531 and one or more diffused impurities 541, although surface contaminants 521 can be produced during the etching process.

FIGS. 5D and 5E show a second cycle of the present invention. As shown in FIG. 5D, a second ultra-thin oxide layer 552 is formed to consume some more of the defects 532 (structural defects) and 542 (diffused impurities). As with the first ultra-thin oxide layer 551, the second ultra-thin oxide layer 552 is preferably from about 5 Å to about 15 Å thick and is more preferably about 10 Å thick, and therefore does not contribute to new defect formation, or the defect formation is minimized. As shown in FIG. 5E, the second ultra-thin oxide layer 552 is then etched away to remove one or more surface defects (not shown) and one or more surface contaminants 521. The etching process also removes one or more diffused impurities 542, and at least partially removes one or more structural defects 532. Again, surface contaminants 522 can be produced during the etching process.

FIGS. 5F and 5G show a third cycle of the present invention. As shown in FIG. 5F, a third ultra-thin oxide layer 553 is formed to consume even more defects 533 (structural defects) and 543 (diffused impurities). As with the ultra-thin oxide layers 551 and 552, the third ultra-thin oxide layer 553 is preferably from about 5 Å to about 15 Å thick and more preferably about 10 Å thick, and therefore does not contribute to new defect formation, or the defects are minimized. As shown in FIG. 1G, the third ultra-thin oxide layer 553 is then etched away to remove one or more surface defects (not shown) and one or more surface contaminants 522. The etching process can also remove one or more diffused impurities 543, and to at least partially remove one or more structural defects 533. Again, surface contaminants 523 can be produced during the etching process. Once the defects are substantially removed from the substrate as shown in FIG. 5G, an additional layer can be formed on the substrate using at least one of a thin film deposition process, an oxidation process, and an implantation process.

Thus, as seen in FIGS. 5A-5G, the multi-step oxide grow and etch process of the present invention may be used to eliminate defects in the surface region of the semiconductor substrate without forming new defects. In particular, the present invention provides a method for growing a thin oxide film less than 15 Å in total thickness. The present inventors have recognized that such a thin film can result in the least disturbance of the silicon lattice or other substrate structure, thus providing the best surface after its removal. Although three cycles are shown in FIGS. 5A -5G, any number of cycles greater than two can be performed in accordance with the present invention. For example, a method using a series of oxidation and etching can be used to create an improved surface layer on a substrate. In one embodiment of the present invention described with respect to FIG. 5, the number of diffusion oxide and etching cycles is determined by monitoring the substrate surface region for high quality surface treatment. Such a high quality surface treatment can be detected with HRTEM (high resolution transmission electron microscopy) to image the silicon lattice at the silicon/dielectric interface. By providing a substrate having fewer defects than conventional substrates, the method of the present invention provides an improved substrate that is critical for advanced logic and memory applications, and a more ideal transistor behavior will result.

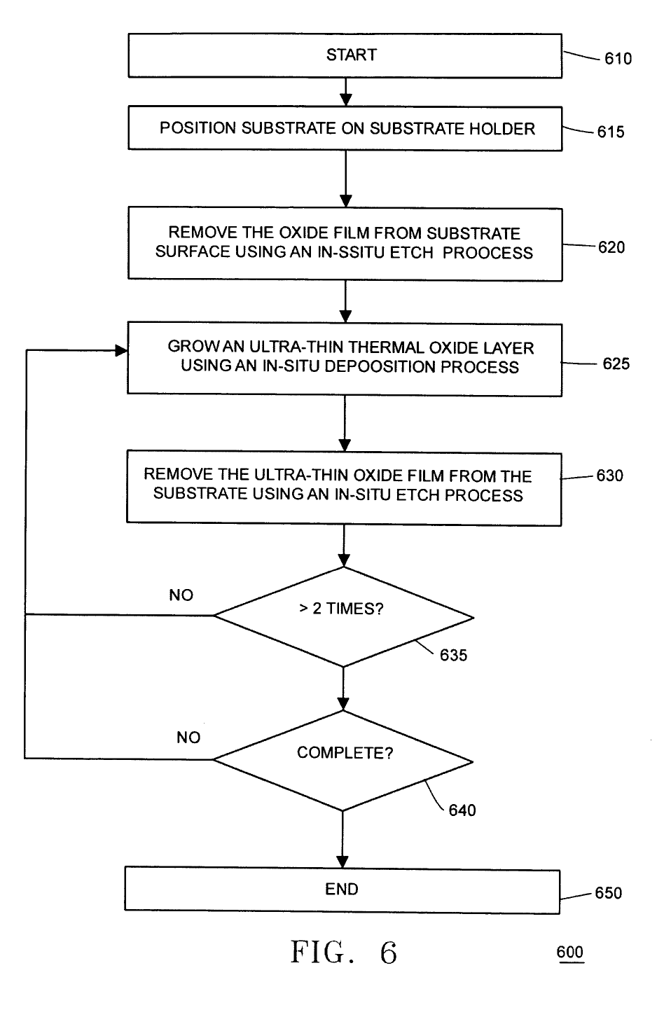

As noted above, the processing systems of FIGS. 1, 2 and 3 may be used to perform the processing steps shown in FIGS. 5A-5G. FIG. 6 shows a flow diagram for a method of processing a substrate in accordance with an embodiment of the present invention. The method of FIG. 6 can also be performed by the systems of FIGS. 1, 2 and 3. The procedure 600 starts in step 610 where Si wafers and/or substrates can be obtained from any of a number of different locations in a semiconductor processing facility.

In 615, a substrate is positioned on a substrate holder. For example, substrates can be positioned on a substrate holder using a transfer system that is coupled to one or more processing chambers.

In 620, an oxide film is removed from the substrate surface using an in-situ wet or dry etch process. For example, the oxide film can be a native oxide or another oxide layer, and the in-situ etch can be performed using a processing gas including anhydrous HF, or HF and steam, or some other such environment that will form a volatile compound with the SiO2 film. For example gases containing H and/or F that evolve H and/or F in a form that will react with the SiO2 such as H2 or F2. In an alternate embodiment, a plasma process can be performed in step 620.

In 625, an ultra-thin thermal oxide layer is grown using an in-situ deposition process. The ultra-thin layer can vary between approximately 5 Å and approximately 15Å. This oxide layer is ideally grown thermally without removal of the substrate from the processing environment to maintain low contamination levels as well as optimum manufacturing efficiency. Thermal oxide layers as thin as 5-15 Å can be formed on the substrate at elevated temperatures (>400C.) either with dilute ambients near atmospheric pressure or at low pressure. The ambient used may contain oxygen, NO, N2O, or some other reactant containing oxygen. In an alternate embodiment, a plasma process can be used to perform step 625.

In 630, the ultra-thin thermal oxide layer is removed using an in-situ wet or dry etch process. For example, the ultra-thin oxide layer can be removed by an etching process that is similar to the process used to remove the original oxide film as stated above. Alternately, the ultra-thin oxide layer can be removed by an etching process that is different than the process used to remove the original oxide film. The etching process itself is only critical in that it not damage the substrate further and that it be compatible with processing hardware. Additionally it is further desired but not required that the etching process be compatible with the oxidation process in terms of temperature and pressure to provide the overall shortest cycle time, thus increasing productivity.

In 635, a query is performed to determine if at least two cycles have been performed. Typically, at least two cycles, such as those described with respect to FIG. 1, are performed in accordance with the present invention. When at least two cycles have not been performed, procedure 600 branches back to 625, where another ultra-thin oxide layer is grown on the substrate. When at least two cycles have been performed, procedure 600 continues to 640 where a query is performed to determine if the process has been completed. When the process has not been completed, procedure 600 branches back to 625 to repeat the oxide growth-etch cycle. When the process has been completed, procedure 600 continues to 645, where the procedure 600 ends.

Process completion can be determined in step 640 in a number of ways. Process completion can be determined using historical data and/or verification of the final substrate condition. In one embodiment, optical measurements are used to determine process completion. For example, the cycle of diffusion and etching can be repeated until the desired volume of Si is removed. Alternately, the cycle of diffusion and etching can be repeated until the desired number of defects in the Si is removed. Also, the cycle of diffusion and etching can be repeated until the desired number of defects in the surface is removed. In addition, the cycle of diffusion and etching can be repeated until the desired number of diffused impurities in the Si is removed. Also, the cycle of diffusion and etching can be repeated until the desired number of surface contaminants is achieved.

After procedure 600 ends, the substrate preferably undergoes further processing within the system without exposing the substrate to an ambient environment. Thus, while the known sacrificial oxide methods described in the Background section above generally expose the treated substrate to ambient environment, which causes further native oxide growth, the method and system of the present invention does not expose the substrate to ambient and the processed surface is preserved until subsequent processing steps are performed, such as thin film deposition steps. Alternately, processing can end after the substrate has been further processed using an oxidation, deposition, or implantation process.

FIG. 7 illustrates a computer system 1201 upon which an embodiment of the present invention may be implemented. The computer system 1201 may be used as the controller 270 or a similar controller that may be used with the systems of FIGS. 1-3 to perform any or all of the functions described above. The computer system 1201 includes a bus 1202 or other communication mechanism for communicating information, and a processor 1203 coupled with the bus 1202 for processing the information. The computer system 1201 also includes a main memory 1204, such as a random access memory (RAM) or other dynamic storage device (e.g., dynamic RAM (DRAM), static RAM (SRAM), and synchronous DRAM (SDRAM)), coupled to the bus 1202 for storing information and instructions to be executed by processor 1203. In addition, the main memory 1204 may be used for storing temporary variables or other intermediate information during the execution of instructions by the processor 1203. The computer system 1201 further includes a read only memory (ROM) 1205 or other static storage device (e.g., programmable ROM (PROM), erasable PROM (EPROM), and electrically erasable PROM (EEPROM)) coupled to the bus 1202 for storing static information and instructions for the processor 1203.

The computer system 1201 also includes a disk controller 1206 coupled to the bus 1202 to control one or more storage devices for storing information and instructions, such as a magnetic hard disk 1207, and a removable media drive 1208 (e.g., floppy disk drive, read-only compact disc drive, read/write compact disc drive, compact disc jukebox, tape drive, and removable magneto-optical drive). The storage devices may be added to the computer system 1201 using an appropriate device interface (e.g., small computer system interface (SCSI), integrated device electronics (IDE), enhanced-IDE (E-IDE), direct memory access (DMA), or ultra-DMA).

The computer system 1201 may also include special purpose logic devices (e.g., application specific integrated circuits (ASICs)) or configurable logic devices (e.g., simple programmable logic devices (SPLDs), complex programmable logic devices (CPLDs), and field programmable gate arrays (FPGAs)). The computer system may also include one or more digital signal processors (DSPs) such as the TMS320 series of chips from Texas Instruments, the DSP56000, DSP56100, DSP56300, DSP56600, and DSP96000 series of chips from Motorola, the DSP1600 and DSP3200 series from Lucent Technologies or the ADSP2100 and ADSP21000 series from Analog Devices. Other processors especially designed to process analog signals that have been converted to the digital domain may also be used.

The computer system 1201 may also include a display controller 1209 coupled to the bus 1202 to control a display 1210, such as a cathode ray tube (CRT), for displaying information to a computer user. The computer system includes input devices, such as a keyboard 1211 and a pointing device 1212, for interacting with a computer user and providing information to the processor 1203. The pointing device 1212, for example, may be a mouse, a trackball, or a pointing stick for communicating direction information and command selections to the processor 1203 and for controlling cursor movement on the display 1210. In addition, a printer may provide printed listings of data stored and/or generated by the computer system 1201.

The computer system 1201 performs a portion or all of the processing steps of the invention in response to the processor 1203 executing one or more sequences of one or more instructions contained in a memory, such as the main memory 1204. Such instructions may be read into the main memory 1204 from another computer readable medium, such as a hard disk 1207 or a removable media drive 1208. One or more processors in a multi-processing arrangement may also be employed to execute the sequences of instructions contained in main memory 1204. In alternative embodiments, hard-wired circuitry may be used in place of or in combination with software instructions. Thus, embodiments are not limited to any specific combination of hardware circuitry and software.

As stated above, the computer system 1201 includes at least one computer readable medium or memory for holding instructions programmed according to the teachings of the invention and for containing data structures, tables, records, or other data described herein. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the computer system 1201, for driving a device or devices for implementing the invention, and for enabling the computer system 1201 to interact with a human user (e.g., print production personnel). Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor 1203 for execution. A computer readable medium may take many forms, including but not limited to, non-volatile media, volatile media, and transmission media. Non-volatile media includes, for example, optical, magnetic disks, and magneto-optical disks, such as the hard disk 1207 or the removable media drive 1208. Volatile media includes dynamic memory, such as the main memory 1204. Transmission media includes coaxial cables, copper wire and fiber optics, including the wires that make up the bus 1202. Transmission media also may also take the form of acoustic or light waves, such as those generated during radio wave and infrared data communications.

Various forms of computer readable media may be involved in carrying out one or more sequences of one or more instructions to processor 1203 for execution. For example, the instructions may initially be carried on a magnetic disk of a remote computer. The remote computer can load the instructions for implementing all or a portion of the present invention remotely into a dynamic memory and send the instructions over a telephone line using a modem. A modem local to the computer system 1201 may receive the data on the telephone line and use an infrared transmitter to convert the data to an infrared signal. An infrared detector coupled to the bus 1202 can receive the data carried in the infrared signal and place the data on the bus 1202. The bus 1202 carries the data to the main memory 1204, from which the processor 1203 retrieves and executes the instructions. The instructions received by the main memory 1204 may optionally be stored on storage device 1207 or 1208 either before or after execution by processor 1203.

The computer system 1201 also includes a communication interface 1213 coupled to the bus 1202. The communication interface 1213 provides a two-way data communication coupling to a network link 1214 that is connected to, for example, a local area network (LAN) 1215, or to another communications network 1216 such as the Internet. For example, the communication interface 1213 may be a network interface card to attach to any packet switched LAN. As another example, the communication interface 1213 may be an asymmetrical digital subscriber line (ADSL) card, an integrated services digital network (ISDN) card or a modem to provide a data communication connection to a corresponding type of communications line. Wireless links may also be implemented. In any such implementation, the communication interface 1213 sends and receives electrical, electromagnetic or optical signals that carry digital data streams representing various types of information.

The network link 1214 typically provides data communication through one or more networks to other data devices. For example, the network link 1214 may provide a connection to another computer through a local network 1215 (e.g., a LAN) or through equipment operated by a service provider, which provides communication services through a communications network 1216. The local network 1214 and the communications network 1216 use, for example, electrical, electromagnetic, or optical signals that carry digital data streams, and the associated physical layer (e.g., CAT 5 cable, coaxial cable, optical fiber, etc). The signals through the various networks and the signals on the network link 1214 and through the communication interface 1213, which carry the digital data to and from the computer system 1201 maybe implemented in baseband signals, or carrier wave based signals. The baseband signals convey the digital data as unmodulated electrical pulses that are descriptive of a stream of digital data bits, where the term “bits” is to be construed broadly to mean symbol, where each symbol conveys at least one or more information bits. The digital data may also be used to modulate a carrier wave, such as with amplitude, phase and/or frequency shift keyed signals that are propagated over a conductive media, or transmitted as electromagnetic waves through a propagation medium. Thus, the digital data may be sent as unmodulated baseband data through a “wired” communication channel and/or sent within a predetermined frequency band, different than baseband, by modulating a carrier wave. The computer system 1201 can transmit and receive data, including program code, through the network(s) 1215 and 1216, the network link 1214, and the communication interface 1213. Moreover, the network link 1214 may provide a connection through a LAN 1215 to a mobile device 1217 such as a personal digital assistant (PDA) laptop computer, or cellular telephone.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

Numerous modifications and variations of the present invention are possible in light of the above teachings. It is therefore to be understood that, within the scope of the appended claims, the invention may be practiced otherwise than as specifically described herein.

1. A method of processing a substrate comprising:
growing a first ultra-thin oxide layer on a surface of the substrate to consume defects in a surface region of the substrate;
etching away at least a portion of the first ultra-thin oxide layer to remove at least some of said consumed defects from the substrate and reveal a subsurface of said substrate;
growing a second ultra-thin oxide layer on said subsurface of said substrate to consume more defects in said surface region of the substrate; and
etching away at least a portion of the second ultra-thin oxide layer to remove at least some of said consumed more defects from the substrate.

2. The method of claim 1, wherein said growing first and second ultra-thin oxide layers each comprise growing an oxide layer having a thickness of between approximately 5 Å and approximately 15 Å.

3. The method of claim 1, further comprising:
monitoring said surface region of the substrate; and
repeatedly growing an additional ultra-tin oxide layer to consume additional defects and etching the additional oxide layer to remove the consumed additional defects based on said monitoring of said surface region.

4. The method of claim 3, wherein said monitoring comprises using high-resolution transmission electron microscopy (HRTEM) data.

5. The method of claim 1, wherein the substrate comprises silicon.

6. The method of claim 1, wherein the substrate comprises at least one of silicon and a silicon alloy.

7. The method of claim 1, further comprising forming an additional layer on one of said first and second oxide layer using at least one of a thin film deposition process, an oxidation process, and an implantation process.

8. The method of claim 1, wherein at least one of said etching steps comprises a dry vapor etch process.

9. The method of claim 1, wherein at least one of said etching steps comprises a wet etch process.

10. The method of claim 1, wherein at least one of said etching steps comprises using a gas including at least one of a hydrogen containing gas, a fluorine containing gas, and a chlorine containing gas.

11. The method of claim 10, wherein said using a gas comprises using a gas comprising at least one of HF, H2, F2, and ClF3.

12. The method of claim 1, further comprising processing a plurality of substrates including said substrate, wherein each of said growing steps and each of said etching steps is performed on each of said plurality of substrates.

13. A semiconductor device comprising a substrate processed in accordance with any one of claims 1-12.

14. A semiconductor processing apparatus comprising:
an oxide chamber configured to form an oxide layer on a semiconductor substrate;
an etch chamber configured to etch the oxide layer; and
a controller configured to cause the processing apparatus to perform the method of any one of claims 1-12.

15. A computer readable medium containing program instructions for execution on a processor, which when executed by the processor, cause a substrate processing apparatus to perform the steps in the method recited in any one of claims 1-12.

16. A substrate processing apparatus comprising:
means for growing a first ultra-thin oxide layer on a surface of the substrate to consume defects in a surface region of the substrate;
means for etching away at least a portion of the first ultra-thin oxide layer to remove at least some of said consumed defects from the substrate and reveal a subsurface of said substrate;
means for growing a second ultra-thin oxide layer on said subsurface of said substrate to consume more defects in said surface region of the substrate; and
means for etching away at least a portion of the second ultra-thin oxide layer to remove at least some of said consumed more defects from the substrate.
